(19) United States
(12) Patent Application Publication
(10) Pub. No.: US 2025/0081717 A1
(43) Pub. Date: Mar. 6, 2025

(54) LIGHT-EMITTING DIODE AND MANUFACTURING METHOD THEREFOR

(71) Applicant: TCL TECHNOLOGY GROUP CORPORATION, Huizhou, Guangdong (CN)

(72) Inventor: Xiongfeng LIN, Huizhou, Guangdong (CN)

(73) Assignee: TCL TECHNOLOGY GROUP CORPORATION, Huizhou, Guangdong (CN)

(21) Appl. No.: 18/725,757

(22) PCT Filed: Nov. 30, 2022
(86) PCT No.: PCT/CN2022/135497

§ 371 Date: Jun. 29, 2024

(30) Foreign Application Priority Data
Dec. 30, 2021 (CN) 202111651257.X

(51) Int. Cl. H10K 50/115; H10K 50/16; H10K 50/805; H10K 71/12; H10K 102/00

(52) U.S. Cl. CPC H10K 50/115; H10K 50/16; H10K 50/805; H10K 71/125; H10K 2102/351

(57) ABSTRACT

A light-emitting diode and a manufacturing method therefor. A light-emitting layer is used as the last layer of a deposited material, so that the corrosion to the light-emitting layer is avoided in the process of preparing other structures on the light-emitting layer, and the stability of the light-emitting layer is improved. Moreover, there is no functional material on the surface of the light-emitting layer to shield emitted light, a contact area of the light-emitting layer and a second electrode layer is not reduced, and a light-emitting rate of the light-emitting layer and the light-emitting efficiency of the light-emitting diode are ensured.

This application claims priority to Chinese Application No. 202111651257.X, entitled “LIGHT-EMITTING DIODE AND MANUFACTURING METHOD THEREFOR”, filed on Dec. 30, 2021. The entire disclosures of the above applications are incorporated herein by reference.

### FIELD OF INVENTION

The present disclosure relates to the technical field of semiconductor devices, in particular to a light-emitting diode and a manufacturing method thereof.

### BACKGROUND

Currently, there are various types of light-emitting diodes, and the more popular ones comprise quantum dot light-emitting diodes and organic light-emitting diodes. Quantum dot light-emitting diodes (QLEDs) are emerging display devices. QLED is a new technology between liquid crystals and organic light-emitting diodes (OLEDs). QLED, like OLED, also has a hole transport layer, a light-emitting layer, and an electron transport layer. A characteristic of QLED is that the light-emitting layer uses inorganic quantum dots with more stable performance. Luminescence stability of inorganic quantum dots is greater than that of organic small molecules and polymers. QLED has good development prospects.

In a current structure of QLED, when a material is deposited on a surface of the light-emitting layer, the light-emitting layer is often damaged. Furthermore, the electron transport layer blocks light, which will greatly affect an overall light output of QLED, thus affecting device performance. Therefore, back-contact devices are used in the existing technology, in which cathode electrodes and anode electrodes are pre-fabricated into interdigitated electrodes by photolithography and physical or chemical deposition, and materials are deposited on the interdigitated electrodes to complete device fabrication. This prevents the light-emitting layer from being damaged during deposition. However, in such a back electrode structure, the cathode electrode and the anode electrode are placed under the light-emitting layer. Therefore, under a same light-emitting area, a contact area between a functional layer and the light-emitting layer in a device with the back electrode structure is half that in a device with a stacked structure, which means an effective contact area is reduced. This directly affects an amount of carrier injection from the functional layer to the light-emitting layer, resulting in low luminous efficiency.

Therefore, it is necessary to solve the problem of how to ensure light extraction efficiency of the light-emitting layer and luminous efficiency of the light-emitting diode without damaging the light-emitting layer.

### SUMMARY

The present disclosure provides a light-emitting diode, which comprises a first electrode layer, a framework layer, a second electrode layer, and a light-emitting layer. The framework layer is disposed on the first electrode layer. A surface of the framework layer close to the first electrode layer has a first opening. A surface of the framework layer away from the first electrode layer has a second opening. The framework layer has a connecting channel connecting the first opening and the second opening. The framework layer is made of an insulating material. The second electrode layer covers the surface of the framework layer away from the first electrode layer and exposes at least a part of the second opening. The light-emitting layer covers the second electrode layer and the part of the second opening. The light-emitting layer penetrates into the connecting channel through the second opening, and the light-emitting layer is in electrical contact with the first electrode layer through the first opening.

Optionally, in some embodiment of the present disclosure, the light-emitting layer comprises a plurality of quantum dots, and a channel size of the connecting channel is greater than a diameter of the quantum dots.

Optionally, in some embodiment of the present disclosure, the framework layer comprises a plurality of nanoparticles, the nanoparticles are stacked, and gaps between the adjacent nanoparticles are combined to form the connecting channel in the framework layer.

Optionally, in some embodiment of the present disclosure, the nanoparticles cover a surface of the first electrode layer to form the skeleton layer.

Optionally, in some embodiment of the present disclosure, the nanoparticles are disposed on parts of a surface of the first electrode layer.

Optionally, in some embodiment of the present disclosure, the nanoparticles form multiple layers or a single layer.

Optionally, in some embodiment of the present disclosure, a diameter of the nanoparticles is 200-1000 nm.

Optionally, in some embodiment of the present disclosure, the second electrode layer is provided with a plurality of mesh holes at the second opening, and the light-emitting layer penetrates into the connecting channel through the mesh holes and the second opening.

Optionally, in some embodiment of the present disclosure, the second electrode layer has a thickness of 30-50 nm.

Optionally, in some embodiment of the present disclosure, the light-emitting diode further comprises a first charge transport layer and a second charge transport layer. The first charge transport layer is disposed on the first electrode layer. The framework layer is disposed on the first charge transport layer, the second electrode layer is disposed on the framework layer. The second charge transport layer is disposed on the second electrode layer, the light-emitting layer is disposed on the second charge transport layer and penetrates into the connecting channel to be electrically connected to the first charge transport layer.

Optionally, in some embodiment of the present disclosure, the second charge transport layer has a thickness of 10-30 nm, and/or the first charge transport layer has a thickness of 10-50 nm.

Optionally, in some embodiment of the present disclosure, the first charge transport layer is disposed on the surface of the first electrode layer to cover the first electrode layer, and/or the second charge transport layer is disposed on a surface of the second electrode layer to cover the second electrode layer.

Optionally, in some embodiment of the present disclosure, the light-emitting layer is a quantum dot light-emitting layer and is made of one or more of CdSe, CdS, ZnSe, ZnS, CdTe, ZnTe, CdZnS, CdZnSe, CdZnTe, ZnSeS, ZnSeTe, ZnTeS, CdSeS, CdSeTe, CdTeS, CdZnSeS, CdZnSeTe, CdZnSTe, CdSeSTe, ZnSeSTe, InP, GaP, GaAs, InAs, InAsP, GaAsP, InGaP, InGaAs, PbS, PbSe, PbTe, PbSeS, PbSeTe, CdZnSe/ZnS, CdZnSeS/ZnS, CdTe/ZnS, CdZnSe/ZnS, CdZnSeS/ZnS, CdTe/ZnS, CdTe/CdSe, CdTe/ZnTe, CdSe/CdS, CdSe/ZnS, InP/ZnS, inorganic perovskite semiconductors, and organic-inorganic hybrid perovskite semiconductors; a general formula of the inorganic perovskite semiconductors is AMX₃, where A is Cs⁺, M is one of Pb²⁺, Sn²⁺, Cu²⁺, Ni²⁺, Cd²⁺, Cr²⁺, Mn²⁺, Co²⁺, Fe²⁺, Ge²⁺, Yb²⁺, Eu²⁺, and X is one of Cl⁻, Br⁻ and I⁻; and a general formula of the organic-inorganic hybrid perovskite semiconductors is BMX₃, where B is an organic amine cation, M is one of Pb²⁺, Sn²⁺, Cu²⁺, Ni²⁺, Cd²⁺, Cr²⁺, Mn²⁺, Co²⁺, Fe²⁺, Ge²⁺, Yb²⁺, Eu²⁺, and X is one of Cl⁻, Br⁻ and I⁻. The first electrode layer is made of one or more of conductive metal and conductive metal oxide, the conductive metal is one or more of zinc, tin, copper, chromium, platinum, nickel, titanium, aluminum, and silver, and the conductive metal oxide is one or more of ITO and FTO. The second electrode layer is made of one or more of conductive metal and conductive metal oxide, the conductive metal is one or more of zinc, tin, copper, chromium, platinum, nickel, titanium, aluminum, and gold, and the conductive metal oxide is one or more of ITO and FTO. The first charge transport layer is made of one or more of ZnO, TiO₂, SnO₂, Ta₂O₃, ZrO₂, NiO, TiLiO, ZnAlO, ZnMgO, ZnSnO, ZnLiO, and InSnO. The second charge transport layer is made of one or more of NiO_{X}, PEDOT:PSS, CuSCN, and CuO_{X}. The insulating material comprises one or more of zirconium dioxide and alumina.

Correspondingly, the present disclosure further provides a method for manufacturing a light-emitting diode, which comprises: forming a first electrode layer on a substrate; forming a framework layer on a surface of the first electrode layer, wherein a surface of the framework layer close to the first electrode layer has a first opening, a surface of the framework layer away from the first electrode layer has a second opening, the framework layer has a connecting channel connecting the first opening and the second opening, and the framework layer is made of an insulating material; evaporating a second electrode layer on a surface of the framework layer, wherein the second electrode layer covers the surface of the framework layer away from the first electrode layer and exposes at least a part of the second opening; and forming a light-emitting layer on the second electrode layer by a solution method, wherein the light-emitting layer covers the second electrode layer and the part of the second opening, the light-emitting layer penetrates into the connecting channel through the second opening, and the light-emitting layer is in electrical contact with the first electrode layer through the first opening.

Optionally, in some embodiment of the present disclosure, the forming the framework layer on the surface of the first electrode layer comprises: preparing a solution comprising an insulating material, and depositing the solution comprising the insulating material on the surface of the first electrode layer by a solution method to form the framework layer.

Optionally, in some embodiment of the present disclosure, the insulating material comprises a plurality of nanoparticles, and after depositing the solution comprising the insulating material on the surface of the first electrode layer, the nanoparticles are stacked, and gaps between the adjacent nanoparticles are combined to form the connecting channel in the framework layer.

Optionally, in some embodiment of the present disclosure, when evaporating the second electrode layer, an evaporation rate is 0.1-2 A/s, an evaporation time is 5000 s-150 s, and the second electrode layer has a thickness of 30-50 nm.

Optionally, in some embodiment of the present disclosure, after forming the first electrode layer on the substrate, the method further comprises: electrochemically depositing a first charge transport layer on a surface of the first electrode layer; or surface oxidizing the first electrode layer to form the first charge transport layer.

Optionally, in some embodiment of the present disclosure, after evaporating the second electrode layer on the surface of the framework layer, the method further comprises: electrochemically depositing a second charge transport layer on a surface of the second electrode layer; or surface oxidizing the second electrode layer to form the second charge transport layer.

Optionally, in some embodiment of the present disclosure, the light-emitting layer is a quantum dot light-emitting layer and is made of one or more of CdSe, CdS, ZnSe, ZnS, CdTe, ZnTe, CdZnS, CdZnSe, CdZnTe, ZnSeS, ZnSeTe, ZnTeS, CdSeS, CdSeTe, CdTeS, CdZnSeS, CdZnSeTe, CdZnSTe, CdSeSTe, ZnSeSTe, InP, GaP, GaAs, InAs, InAsP, GaAsP, InGaP, InGaAs, PbS, PbSe, PbTe, PbSeS, PbSeTe, CdZnSe/ZnS, CdZnSeS/ZnS, CdTe/ZnS, CdZnSe/ZnS, CdZnSeS/ZnS, CdTe/ZnS, CdTe/CdSe, CdTe/ZnTe, CdSe/CdS, CdSe/ZnS, InP/ZnS, inorganic perovskite semiconductors, and organic-inorganic hybrid perovskite semiconductors; a general formula of the inorganic perovskite semiconductors is AMX₃, where A is Cs⁺, M is one of Pb²⁺, Sn²⁺, Cu²⁺, Ni²⁺, Cd²⁺, Cr²⁺, Mn²⁺, Co²⁺, Fe²⁺, Ge²⁺, Yb²⁺, Eu²⁺, and X is one of Cl⁻, Br⁻ and I⁻; and a general formula of the organic-inorganic hybrid perovskite semiconductors is BMX₃, where B is an organic amine cation, M is one of Pb²⁺, Sn²⁺, Cu²⁺, Ni²⁺, Cd²⁺, Cr²⁺, Mn²⁺, Co²⁺, Fe²⁺, Ge²⁺, Yb²⁺, Eu²⁺, and X is one of Cl⁻, Br⁻ and I⁻. The first electrode layer is made of one or more of conductive metal and conductive metal oxide, the conductive metal is one or more of zinc, tin, copper, chromium, platinum, nickel, titanium, aluminum, and silver, and the conductive metal oxide is one or more of ITO and FTO. The second electrode layer is made of one or more of conductive metal and conductive metal oxide, the conductive metal is one or more of zinc, tin, copper, chromium, platinum, nickel, titanium, aluminum, and gold, and the conductive metal oxide is one or more of ITO and FTO. The first charge transport layer is made of one or more of ZnO, TiO₂, SnO₂, Ta₂O₃, ZrO₂, NiO, TiLiO, ZnAlO, ZnMgO, ZnSnO, ZnLiO, and InSnO. The second charge transport layer is made of one or more of NiO_{X}, PEDOT:PSS, CuSCN, and CuO_{X}. The insulating material comprises one or more of zirconium dioxide and alumina.

In the light-emitting diode and the manufacturing method thereof provided by the present disclosure, depositing the light-emitting layer as the last layer prevents the light-emitting layer from being corroded when other structures are formed on the light-emitting layer, thereby improving stability of the light-emitting layer. Moreover, there is no functional material that blocks light on a surface of the light-emitting layer, and a contact area between the light-emitting layer and the second electrode layer is not reduced, thereby ensuring light extraction efficiency of the light-emitting layer and luminous efficiency of the light-emitting diode.

### BRIEF DESCRIPTION OF DRAWINGS

In order to clearly illustrate the technical solutions in the embodiments of the present disclosure, the drawings required to be used in the description of the embodiments will be briefly introduced below. It is obvious that the drawings described below are only some embodiments of the present disclosure, and for those skilled in the art, other drawings can be obtained according to these drawings without creative labor.

FIG. 1 is a schematic flow chart of a method for manufacturing a light-emitting diode according to an embodiment of the present disclosure.

FIG. 2 is a schematic cross-sectional view of the light-emitting diode according to an embodiment of the present disclosure.

FIG. 3 is a schematic flow chart of the method for manufacturing the light-emitting diode according to another embodiment of the present disclosure.

FIG. 4 is a schematic flow chart of the method for manufacturing the light-emitting diode according to Example 1 of the present disclosure.

FIG. 5 is a schematic flow chart of the method for manufacturing the light-emitting diode according to Example 2 of the present disclosure.

FIG. 6 is a graph of experimental data of Examples 1-2 and Comparative Example 1.

### ELEMENT SYMBOL DESCRIPTION

1—substrate 1, 2—first electrode layer 2, 3—framework layer 3, 4—second electrode layer 4, 5—light-emitting layer 5, 31—connecting channel 31, 32—nanoparticles 32, 41—mesh holes 41.

### DETAILED DESCRIPTION

The technical solutions in the embodiments of the present disclosure will be clearly and completely described below in conjunction with the accompanying drawings in the embodiments of the present disclosure, and it is obvious that the described embodiments are only part of the embodiments of the present disclosure, not all embodiments. Based on the embodiments in the present disclosure, all other embodiments obtained by a person skilled in the art without creative work fall within the scope of protection of the present disclosure.

In addition, it should be understood that the specific embodiments described herein are only for the purpose of illustrating and interpreting the present disclosure and are not intended to limit the present disclosure. In the present disclosure, in the absence of a statement to the contrary, the orientation words used such as “up” and “down” refer specifically to the orientation of the surface in the drawings. In addition, in the description of this application, the term “including” means “including but not limited to”. The various embodiments of the present disclosure may exist in the form of a scope, and it should be understood that the description in the form of a scope is merely for convenience and conciseness and should not be construed as a hard limitation on the scope of the present disclosure; For example, a description of the scope from 1 to 6 should be considered to have specifically disclosed sub-scopes, such as from 1 to 3, from 1 to 4, from 1 to 5, from 2 to 4, from 2 to 6, from 3 to 6, etc., as well as a single number in said range, such as 1, 2, 3, 4, 5 and 6, which would apply regardless of the scope. In addition, whenever a numeric range is indicated in this document, it means any quoted number (fraction or integer) that includes the range referred to.

In the present disclosure, the term “and/or” indicates an association of the associated objects, indicating that there can be three kinds of relationships, for example, A and/or B, which can be denoted as: the case that A exists alone, that A and B exist at the same time, and that B exists alone. A and B can be singular or plural.

In this application, “at least one” means one or more and “many” means two or more of them. “At least one”, “at least one of the following”, or similar expressions refers to any combination of these terms, including any combination of single or plural terms. For example, “at least one of a, b, or c”, or, “at least one of a, b, and c” can be indicated as: a, b, c, a-b (i.e., a and b), a-c, b-c, or a-b-c, where a, b, and c can be single or plural.

A structure of a quantum dot light-emitting diode (QLED) is similar to a structure of an organic light-emitting diode (OLED). They are both sandwich structures mainly composed of a hole transport layer, a light-emitting layer, and an electron transport layer. A core technology of QLED is quantum dots. Quantum dots are particles with a diameter of less than 10 nm and are composed of zinc, cadmium, sulfur and selenium atoms. Quantum dots have an extremely special property: when quantum dots are stimulated by light or electricity, they emit a colored light. The color of the colored light is determined by a material, a size, and a shape of the quantum dots. Because quantum dots have this property, they can change a color of a light emitted by a light source. A wavelength range of a light emitted by quantum dots is very narrow, and a color of the light is relatively pure and can be adjusted. Therefore, a picture displayed by a quantum dot display will be clearer and brighter than that displayed by a liquid crystal display.

Compared with OLED, QLED is characterized by its luminous material being inorganic quantum dots with more stable performance. Quantum dots exhibit excellent physical properties, especially optical properties, due to their unique quantum size effect, macroscopic quantum tunneling effect, and surface effect. Compared with organic fluorescent dyes, quantum dots prepared by a colloidal method have advantages of adjustable spectrum, high luminous intensity, high color purity, long fluorescence lifetime, and being able to excite multi-color fluorescence as a single light source. Furthermore, QLED is expected to become the next generation of flat panel displays due to its long life, simple packaging process or no need for packaging, and thus has broad development prospects. QLED emits light based on electroluminescence of inorganic semiconductor quantum dots. Theoretically, stability of inorganic semiconductor quantum dots is greater than that of organic small molecules and polymers. On the other hand, due to a quantum confinement effect, a luminous width of quantum dots is smaller, resulting in better color purity. Currently, luminous efficiency of QLED has basically met commercial needs.

However, a service life of actual QLED devices currently prepared is far from a theoretical life. Because a QLED device has a sandwich structure, depositing a material on a surface of a quantum dot (QD) layer (light-emitting layer) tends to damage the QD layer, and blocking light by the electron transport layer affects an overall light output of the QLED device, thereby affecting device performance.

In order to avoid negative impact caused by a device structure, back-contact devices are used in the existing technology, in which cathode electrodes and anode electrodes are pre-fabricated into interdigitated electrodes by photolithography and physical or chemical deposition, and QD materials are deposited on the interdigitated electrodes to complete device fabrication. This structure avoids damage to a QD layer when depositing a functional layer and impact of the functional layer on light extraction efficiency, thereby improving device performance. However, in such a back electrode structure, the cathode electrode and the anode electrode are placed under the light-emitting layer. Therefore, under a same light-emitting area, a contact area between a functional layer and the QD layer in a device with the back electrode structure is half that in a device with a stacked structure. The reduced effective contact area affects an amount of carrier injection from the functional layer to the QD layer, thereby affecting luminous efficiency of the device. In addition, back electrodes are usually made by photolithography, but the photolithography is time-consuming and costly, and is not a better option for mass production.

Please refer to FIG. 2, which is a schematic structural diagram of a light-emitting diode according to an embodiment of the present disclosure. The present disclosure provides a light-emitting diode, which comprises a first electrode layer 2, a framework layer 3, a second electrode layer 4, and a light-emitting layer 5. The framework layer 3 is disposed on the first electrode layer 2. A surface of the framework layer 3 close to the first electrode layer 2 has a first opening. A surface of the framework layer 3 away from the first electrode layer 2 has a second opening. The framework layer 3 has a connecting channel 31 connecting the first opening and the second opening. The framework layer 3 is made of an insulating material. The second electrode layer 4 covers the surface of the framework layer 3 away from the first electrode layer 2 and exposes at least a part of the second opening. The light-emitting layer 5 covers the second electrode layer 4 and the part of the second opening. The light-emitting layer 5 penetrates into the connecting channel 31 through the second opening, and the light-emitting layer 5 is in electrical contact with the first electrode layer 2 through the first opening. Depositing the light-emitting layer 5 as the last layer prevents the light-emitting layer 5 from being corroded when other structures are formed on the light-emitting layer 5, thereby improving stability of the light-emitting layer 5. Moreover, there is no functional material that blocks light on a surface of the light-emitting layer 5, and a contact area between the light-emitting layer 5 and the second electrode layer 4 is not reduced, thereby ensuring light extraction efficiency of the light-emitting layer 5 and luminous efficiency of the light-emitting diode.

Specifically, the connecting channel 31 is actually a plurality of channels with random directions inside the framework layer 3 and penetrating an entirety of the framework layer 3, so that the light-emitting layer 5 can flow to a surface of the first electrode layer 2 through the connecting channel 31, thereby achieving electrical contact between the light-emitting layer 5 and the first electrode layer 2. Because evaporation is directional and the connecting channel 31 has channels with random directions, the second electrode layer 4 formed by evaporation will not completely block the channels. Therefore, the light-emitting layer 5 can easily flow onto the first electrode layer 2. Specifically, the first opening and the second opening may be staggered, so that when the second electrode layer 4 is evaporated, the second electrode layer 4 will not cover the first opening. The framework layer 3 can isolate the first electrode layer 2 and the second electrode layer 4. The light-emitting layer 5 is electrically connected to the first electrode layer 2 and the second electrode layer 4 at the same time, meeting a working requirement of the light-emitting layer 5. Furthermore, a part of the light-emitting layer 5 on the second electrode layer 4 is the last layer, so that there is no functional layer that blocks light, thereby improving the light extraction efficiency of the light-emitting diode.

In some embodiments of the present disclosure, the light-emitting layer 5 comprises a plurality of quantum dots. A channel size of the connecting channel 31 is greater than a diameter of the quantum dots, so that the quantum dots can pass through the connecting channel 31 smoothly. The light-emitting layer 5 is a quantum dot light-emitting layer 5. The light-emitting layer 5 is made of one or more of CdSe, CdS, ZnSe, ZnS, CdTe, ZnTe, CdZnS, CdZnSe, CdZnTe, ZnSeS, ZnSeTe, ZnTeS, CdSeS, CdSeTe, CdTeS, CdZnSeS, CdZnSeTe, CdZnSTe, CdSeSTe, ZnSeSTe, InP, GaP, GaAs, InAs, InAsP, GaAsP, InGaP, InGaAs, PbS, PbSe, PbTe, PbSeS, PbSeTe, CdZnSe/ZnS, CdZnSeS/ZnS, CdTe/ZnS, CdZnSe/ZnS, CdZnSeS/ZnS, CdTe/ZnS, CdTe/CdSe, CdTe/ZnTe, CdSe/CdS, CdSe/ZnS, InP/ZnS, inorganic perovskite semiconductors, and organic-inorganic hybrid perovskite semiconductors. A general formula of the inorganic perovskite semiconductors is AMX₃, where A is Cs⁺, M is one of Pb²⁺, Sn²⁺, Cu²⁺, Ni²⁺, Cd²⁺, Cr²⁺, Mn²⁺, Co²⁺, Fe²⁺, Ge²⁺, Yb²⁺, Eu²⁺, and X is one of Cl⁻, Br⁻ and I⁻. A general formula of the organic-inorganic hybrid perovskite semiconductors is BMX₃, where B is an organic amine cation, M is one of Pb²⁺, Sn²⁺, Cu²⁺, Ni²⁺, Cd²⁺, Cr²⁺, Mn²⁺, Co²⁺, Fe²⁺, Ge²⁺, Yb²⁺, Eu²⁺, and X is one of Cl⁻, Br⁻ and I⁻.

In some embodiments of the present disclosure, the framework layer 3 comprises a plurality of nanoparticles 32. The nanoparticles 32 are stacked, and gaps between the adjacent nanoparticles 32 are combined to form the connecting channel 31 in the framework layer 3. A surface of the nanoparticle 32 has protruding structures, and accordingly the second electrode layer 4 also has protruding structures. Compared with a planar structure, this increases the contact area between the second electrode layer 4 and the light-emitting layer 5, thereby increasing the luminous efficiency. When the second electrode layer 4 is evaporated, it will leak into the connecting channel 31 through the second opening. Because evaporation is directional, it is difficult for the second electrode layer 4 to block the three-dimensional connecting channel 31. The second electrode layer 4 has a plurality of mesh holes 41 at the second opening, and has an integrated structure at other positions. Specifically, there are multiple first openings and multiple second openings, which are evenly distributed on upper and lower surfaces of the framework layer 3. Specifically, gaps between the nanoparticles 32 close to the first electrode layer 2 are the first openings. Gaps between the nanoparticles 32 close to the second electrode layer 4 are the second openings. The framework layer 3 is made of one or more of zirconium dioxide nanospheres and alumina nanospheres.

In some embodiments of the present disclosure, a diameter of the nanoparticles 32 is 200-1000 nm. Nearly micron-sized nanoparticles 32 from gaps large enough for the quantum dots to pass through. The quantum dots generally have a size of several nanometers or more than ten nanometers. The nanoparticles 32 comprise at least one of zirconium dioxide nanospheres and alumina nanospheres, and may be other insulating nanospheres. In these embodiment, the framework layer 3 is deposited on the first electrode layer 2 by a solution method.

In some embodiments of the present disclosure, the second electrode layer 4 has a thickness of 30-50 nm. When evaporating a nano-sized electrode material, micron-sized holes will not be completely filled with the electrode material, which facilitates entry of a luminous material into the holes and increases a contact area of the luminous material. If the second electrode layer 4 is too thin, the second electrode layer 4 will form islands on the nanoparticles 32 that cannot be connected to each other. If the second electrode layer 4 is too thick, the second electrode layer 4 will fill the gaps between the nanoparticles 32, so that the light-emitting layer 5 cannot penetrate downward. The second electrode layer 4 is made of one or more of conductive metal and conductive metal oxide. The conductive metal is one or more of zinc, tin, copper, chromium, platinum, nickel, titanium, aluminum, and gold. The conductive metal oxide is one or more of ITO and FTO. The first electrode layer 2 is made of one or more of conductive metal and conductive metal oxide. The conductive metal is one or more of zinc, tin, copper, chromium, platinum, nickel, titanium, aluminum, and silver. The conductive metal oxide is one or more of ITO and FTO.

In some embodiments of the present disclosure, the light-emitting diode further comprises a first charge transport layer and a second charge transport layer. The first charge transport layer is disposed on the first electrode layer 2. The framework layer 3 is disposed on the first charge transport layer. The second electrode layer 4 is disposed on the framework layer 3. The second charge transport layer is disposed on the second electrode layer 4. The light-emitting layer 5 is disposed on the second charge transport layer and penetrates into the connecting channel 31 to be electrically connected to the first charge transport layer. Specifically, the second charge transport layer has a thickness of 10-30 nm. If the second charge transport layer is too thick, the second charge transport layer may block the holes and affect charge transport performance. If the second charge transport layer is too thin, film formation of the second charge transport layer will be poor, which is not conducive to electron injection. In some embodiments of the present disclosure, the first charge transport layer is deposited on the surface of the first electrode layer 2 to cover the first electrode layer 2. In some embodiments of the present disclosure, the second charge transport layer is deposited on a surface of the second electrode layer 4 to cover the second electrode layer 4. The second charge transport layer may be a hole transport layer. In some embodiments of the present disclosure, the first charge transport layer has a thickness of 10-50 nm.

In some embodiments of the present disclosure, the first electrode layer 2 may be a cathode electrode or an anode electrode, and the second electrode layer 4 is the corresponding anode electrode or cathode electrode. The first charge transport layer is an electron transport layer, and the second charge transport layer is a hole transport layer. A material of the electron transport layer may be selected from, but is not limited to, ZnO, TiO₂, SnO₂, Ta₂O₃, ZrO₂, NiO, TiLiO, ZnAlO, ZnMgO, ZnSnO, ZnLiO, and InSnO. A material of the hole transport layer may be selected from, but is not limited to, NiO_{X}, PEDOT:PSS, CuSCN, and CuO_{X}.

Specifically, in this embodiment, the first electrode layer 2 and the second electrode layer 4 have been prepared before the light-emitting layer 5 is prepared, and the light-emitting layer 5 is deposited on the second electrode layer 4 as the last layer. This prevents the light-emitting layer 5 from being corroded when other structures are formed on the light-emitting layer 5, thereby improving the stability of the light-emitting layer 5. For example, preparing the second charge transport layer on the second electrode layer 4 requires placing an entire structure of the light-emitting diode into a plating solution. This embodiment can prevent the plating solution from corroding the light-emitting layer 5.

In some embodiments of the present disclosure, the nanoparticles 32 may be disposed on parts of the surface of the first electrode layer 2, or may cover an entirety of the surface of the first electrode layer 2. If the nanoparticles 32 are disposed on the parts, spaces on other parts may be filled with a conventional insulating material. The nanoparticles 32 may be uniformly distributed in the framework layer 3 or non-uniformly distributed in the framework layer 3. The nanoparticles 32 may form multiple layers or a single layer.

The present disclosure provides a quantum dot light-emitting diode (QLED), in which the light-emitting layer 5 is made by depositing quantum dots. In order for the quantum dots to smoothly penetrate into the connecting channel 31 of the framework layer 3 and make electrical contact with the first electrode layer 2, the channel size of the connecting channel 31 should be greater than the diameter of the quantum dots. Preferably, a diameter of the connecting channel 31 may be greater than 20 nm, so as to facilitate the quantum dots to pass through the connecting channel 31, thereby achieving electrical connection between the light-emitting layer 5 and the first electrode layer 2, and the second electrode layer 4. Furthermore, the light-emitting layer 5 is disposed on an upper surface of the second electrode layer 4, which avoids the second electrode layer 4 from blocking a light of the light-emitting layer 5, thereby improving the luminous efficiency.

The present disclosure provides an organic light-emitting diode (OLED), in which the light-emitting layer 5 is made of an organic light-emitting material. The organic light-emitting material is dissolved in a solvent, and then injected onto the surface of the first electrode layer 2 through the mesh holes 41 and the connecting channel 31. Therefore, the light-emitting layer 5 is electrically connected to the first electrode layer 2. Furthermore, a part of the light-emitting layer 5 on the surface of the second electrode layer 4 is electrically connected to the second electrode layer 4.

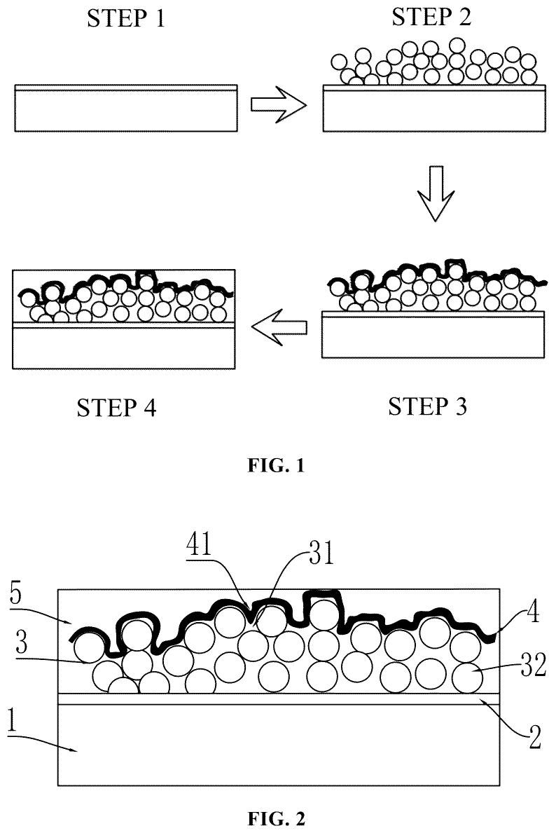

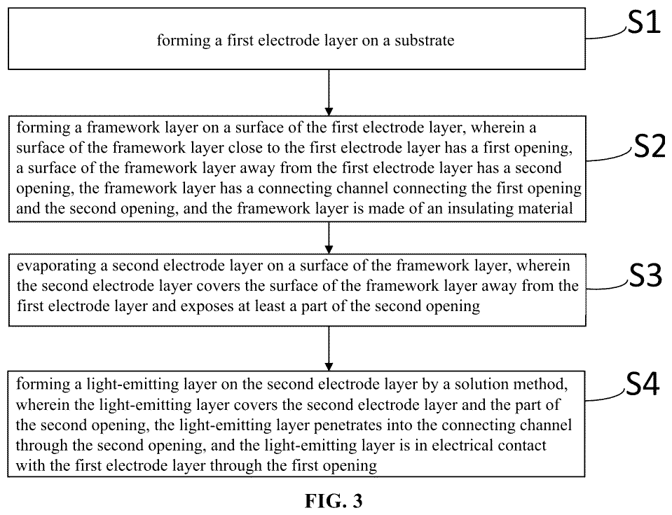

Please refer to FIG. 1 and FIG. 3, the present disclosure provides a method for manufacturing a light-emitting diode, which comprises the following steps.
S1: forming a first electrode layer 2 on a substrate 1.
S2: forming a framework layer 3 on a surface of the first electrode layer 2, wherein a surface of the framework layer 3 close to the first electrode layer 2 has a first opening, a surface of the framework layer 3 away from the first electrode layer 2 has a second opening, the framework layer 3 has a connecting channel 31 connecting the first opening and the second opening, and the framework layer 3 is made of an insulating material.
S3: evaporating a second electrode layer 4 on a surface of the framework layer 3, wherein the second electrode layer 4 covers the surface of the framework layer 3 away from the first electrode layer 2 and exposes at least a part of the second opening.
S4: forming a light-emitting layer 5 on the second electrode layer 4 by a solution method, wherein the light-emitting layer 5 covers the second electrode layer 4 and the part of the second opening, the light-emitting layer 5 penetrates into the connecting channel 31 through the second opening, and the light-emitting layer 5 is in electrical contact with the first electrode layer 2 through the first opening.

The first electrode layer 2 may be deposited on the glass substrate 1 using a solution method. The first electrode layer 2 may be made of a conductive metal such as aluminum, silver, copper, or titanium, or a conductive metal oxide such as ITO or FTO, and may have a thickness of 100-1000 nm. In step S4, the second electrode layer 4 is directionally evaporated. The second electrode layer 4 may be made of a conductive metal such as nickel, gold, platinum, or chromium, and may have a thickness of 30-50 nm.

In some embodiments of the present disclosure, the step of forming the framework layer 3 by a solution method further comprises: forming a plurality of nanoparticles 32 on the surface of the first electrode layer 2 by the solution method, wherein gaps between the adjacent nanoparticles 32 form the connecting channel 31. The framework layer 3 is deposited by the solution method, and may consist of insulating nanospheres such as zirconium dioxide or alumina nanospheres. A diameter of the nanospheres may be 200-1000 nm. Specifically, a plurality of zirconium dioxide nanoparticles with a particle size of 200 nm are formed on the first electrode layer 2 by the solution method, wherein a solution concentration may be 20 mg/mL, a rotation speed may be 2000 rpm, and a time may be 30 seconds. The larger the particle size of the zirconium dioxide nanoparticles, the larger the quantum dots that can pass through the connecting channel 31, which may cause other structural layers to leak into the connecting channel 31. If the particle size of the zirconium dioxide nanoparticles is too small, it will be difficult for the quantum dots to pass through the connecting channel 31. Similarly, the higher the solution concentration, the more zirconium dioxide nanoparticles in the framework layer 3, the closer the adjacent nanoparticles are, and the smaller the channel size of the connecting channel 31. The lower the solution concentration, the larger the channel size of the connecting channel 31, which will easily lead to leakage of other structural layers.

In some embodiments of the present disclosure, the step of forming the framework layer 3 comprises: preparing a solution comprising an insulating material of the nanoparticles 32, and depositing the solution comprising the insulating material on the surface of the first electrode layer 2 through the solution method to form the framework layer 3, wherein the nanoparticles 32 are stacked to form the framework layer 3, and the gaps between the adjacent nanoparticles 32 are combined to form the connecting channel 31.

In some embodiments of the present disclosure, in the step of evaporating the second electrode layer 4, an evaporation rate is 0.1-2 A/s, and an evaporation time is 5000 s-150 s. The second electrode layer 4 has a thickness of 30-50 nm. If the evaporation rate is too fast, a density of the material will decrease, affecting transportation. If the evaporation rate is too slow, it will take time. The shorter the evaporation time, the smaller the thickness. The longer the evaporation time, the greater the thickness.

In some embodiments of the present disclosure, after forming the first electrode layer 2, a first charge transport layer is electrochemically deposited on the surface of the first electrode layer 2. Alternatively, after forming the first electrode layer 2, the first electrode layer 2 is surface oxidized to form a first charge transport layer. Specifically, the first charge transport layer is an electron transport layer, and a material of the electron transport layer may be selected from, but is not limited to, ZnO, TiO₂, SnO₂, Ta₂O₃, ZrO₂, NiO, TiLiO, ZnAlO, ZnMgO, ZnSnO, ZnLiO, and InSnO.

In some embodiments of the present disclosure, after forming the second electrode layer 4, a second charge transport layer is electrochemically deposited on a surface of the second electrode layer 4. Alternatively, after forming the second electrode layer 4, the second electrode layer 4 is surface oxidized to form a second charge transport layer. The second charge transport layer is a hole transport layer. If the second transport layer is formed by oxidation, a material of the hole transport layer may be selected from, but is not limited to, NiOx and CuOx. If the second transport layer is electrochemically deposited, the material of the hole transport layer may be selected from, but is not limited to, NiOx, PEDOT:PSS, CuSCN, and CuOx.

In some embodiments, in the steps of forming the first electrode layer 2, the second electrode layer 4, and the light-emitting layer 5, the layers may be formed by technical means well known in the art, such as chemical methods or physical methods. Chemical methods comprise chemical vapor deposition, continuous ion layer adsorption and reaction, anodizing, electrodeposition, and co-precipitation. The physical methods comprise physical coating methods or solution methods. Specifically, the physical coating methods comprise thermal evaporation coating, electron beam evaporation coating, magnetron sputtering, multi-arc ion coating, physical vapor deposition, atomic layer deposition, and pulse laser deposition. The solution methods comprise spin coating, printing, inkjet printing, blade coating, dip-coating, dipping, spray coating, roll coating, casting, slit coating, and strip coating. For specific processing steps and processing conditions, reference may be made to common methods in the field and will not be described in detail herein.

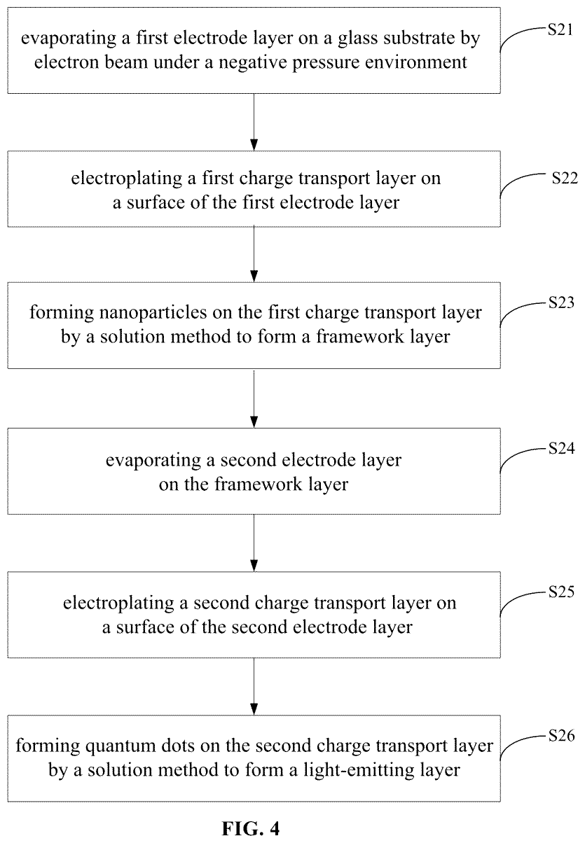

Example 1: please refer to FIG. 4, this example comprises the following steps.
Step S21: evaporating a first electrode layer 2 on a glass substrate 1 by electron beam under a negative pressure environment.
Step S22: electroplating a first charge transport layer on a surface of the first electrode layer 2.

An electroplating solution may be Zn(NO₃)₂ solution.
Step S23: forming nanoparticles 32 on the first charge transport layer by a solution method to form a framework layer 3.
Step S24: evaporating a second electrode layer 4 on the framework layer 3.
Step S25: electroplating a second charge transport layer on a surface of the second electrode layer 4.

An electroplating solution is sodium polystyrene sulfonate and 3,4-ethylenedioxythiophene aqueous solution.
Step S26: forming quantum dots on the second charge transport layer by a solution method to form a light-emitting layer 5.

Specifically, the first electrode layer 2 is placed in a Zn(NO₃)₂ solution (concentration: 130 mM, temperature: 90° C.). A voltage of −1.3V is applied to the first electrode layer 2 for 120 seconds. After stopping applying the voltage to the first electrode layer 2, the first electrode layer 2 is rinsed with deionized water to obtain the first charge transport layer. The second electrode layer 4 is placed in 0.1M sodium polystyrene sulfonate (PSSNa) and 0.015M 3,4-ethylenedioxythiophene (EDOT) aqueous solution. A voltage of 1.1V is applied to the second electrode layer 4 for 120 seconds. After stopping applying the voltage to the second electrode layer 4, the second electrode layer 4 is rinsed with deionized water to obtain the second charge transport layer.

Its specific process flow is as follows.
Step 1: evaporating Ag on the glass substrate 1 by electron beam under a vacuum of 3×10⁻⁴ Pa, with a speed of 1 Angstrom/second, a time of 1000 seconds, and a thickness of 100 nm, to form the first electrode layer 2.
Step 2: placing the first electrode layer 2 in the Zn(NO₃)₂ solution (concentration: 130 mM, temperature: 90° C.), applying the voltage of −1.3V to the first electrode layer 2 for 120 seconds, and rinsing the first electrode layer 2 with deionized water after stopping applying the voltage to obtain the first charge transport layer.
Step 3: forming zirconium dioxide nanoparticles with a particle size of 200 nm on the first charge transport layer through the solution method, with a solution concentration of 20 mg/mL, a rotation speed of 2000 rpm, and a time of 30 seconds, to form the framework layer 3.
Step 4: evaporating Au on the framework layer 3 by electron beam under a vacuum of 3×10⁻⁴ Pa, with a speed of 1 Angstrom/second, a time of 500 seconds, and a thickness of 50 nm, to obtain the second electrode layer 4.
Step 5: placing the second electrode layer 4 in 0.1M polystyrene sulfonate sodium (PSSNa) and 0.015M 3,4-ethylenedioxythiophene (EDOT) aqueous solution, applying the voltage of 1.1V to the second electrode layer 4 for 120 seconds, and rinsing the second electrode layer 4 with deionized water after stopping applying the voltage to obtain the second charge transport layer.
Step 6: forming the quantum dots using the solution method (20 mg/mL) on the second charge transport layer. First let it stand for 5 seconds to allow a solution in the solution method to penetrate into a porous structure of the framework layer 3, then rotate it at 2000 rpm for 30 seconds to form a film.
Step 7: testing JVL data of the obtained device to determine electrical performance of the obtained device.

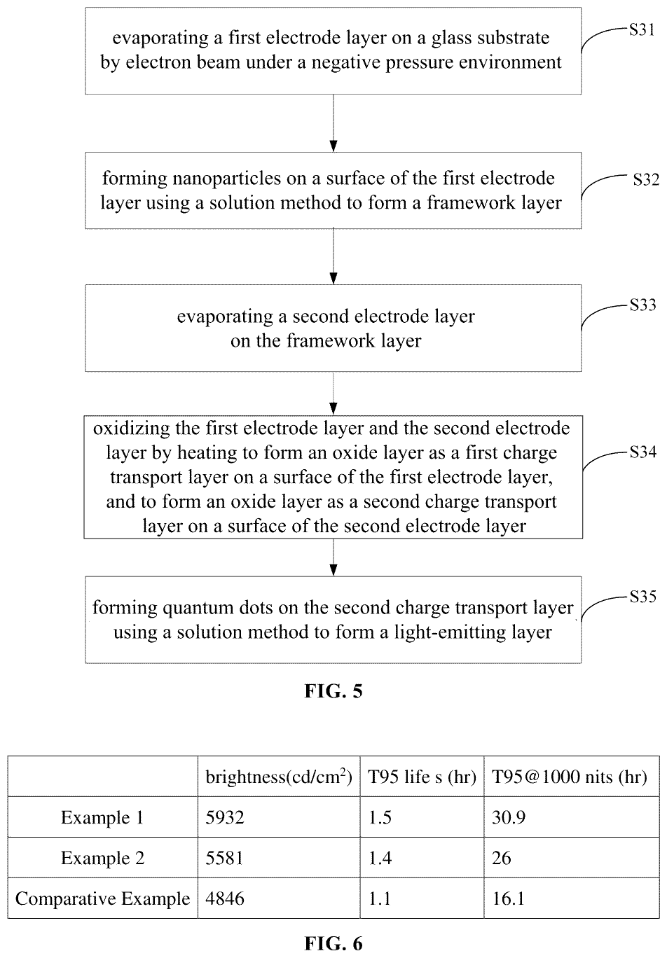

Example 2: please refer to FIG. 5, this example comprises the following steps.
Step S31: evaporating a first electrode layer 2 on a glass substrate 1 by electron beam under a negative pressure environment.
Step S32: forming nanoparticles 32 on a surface of the first electrode layer 2 using a solution method to form a framework layer 3.
Step S33: evaporating a second electrode layer 4 on the framework layer 3.
Step S34: oxidizing the first electrode layer 2 and the second electrode layer 4 by heating to form an oxide layer as a first charge transport layer on a surface of the first electrode layer 2, and to form an oxide layer as a second charge transport layer on a surface of the second electrode layer 4.
Step S35: forming quantum dots on the second charge transport layer using a solution method to form a light-emitting layer 5.

Specifically, a Ti cathode electrode and a Ni anode electrode are heated at 300° C. for 20 minutes for oxidation to form the first charge transport layer and the second charge transport layer, respectively.

Its specific process flow is as follows.
Step 1: evaporating Ti on the glass substrate 1 by electron beam under a vacuum of 3×10⁻⁴ Pa, with a speed of 1 Angstrom/second, a time of 1000 seconds, and a thickness of 100 nm, to form the first electrode layer 2.
Step 2: forming zirconium dioxide nanoparticles with a particle size of 200 nm on the first electrode layer 2 through the solution method, with a solution concentration of 20 mg/mL, a rotation speed of 2000 rpm, and a time of 30 seconds, to form the framework layer 3.
Step 3: evaporating Ni on the framework layer 3 by electron beam under a vacuum of 3×10⁻⁴ Pa, with a speed of 1 Angstrom/second, a time of 500 seconds, and a thickness of 50 nm, to obtain the second electrode layer 4.
Step 4: placing the above electrodes on a heating table, and oxidizing them at 300 C for 20 minutes, wherein a Ti surface of the first electrode layer 2 is oxidized into TiO₂ (the first charge transport layer) and a Ni surface of the second electrode layer 4 is oxidized into NiOx (the second charge transport layer).
Step 5: forming the quantum dots using the solution method (20 mg/mL) on the second charge transport layer. First let it stand for 5 seconds to allow a solution in the solution method to penetrate into a porous structure of the framework layer 3, then rotate it at 2000 rpm for 30 seconds to form a film.
Step 6: testing JVL data of the obtained device to determine electrical performance of the obtained device.

Comparative Example: this comparative example is a conventional non-porous back contact device. Its specific process flow is as follows.
Step 1: in a yellow light room with a class 100, preparing AZ1512 photoresist on a glass substrate using a solution method, rotating it at 3000 rpm for 30 seconds, and then heating it to 110° C. for 2 minutes.
Step 2: using a photomask to expose the photoresist to ultraviolet 1 light for 5 seconds.
Step 3: developing the exposed photoresist in AZ726 developer (developer: water is 3:1) for 25 seconds.
Step 4: using the photoresist as an evaporation mask, and evaporating Al by electron beam under a vacuum of 3×10⁻⁴ Pa, with a speed of 1 Angstrom/second, a time of 300 seconds, and a thickness of 30 nm, to form a Al finger electrode comprising two Al electrodes.
Step 5: removing the photoresist by ultrasonic waves in acetone.
Step 6: placing the Al finger electrode in a Zn(NO₃)₂ solution (concentration: 130 mM, temperature: 90° C.), applying a voltage of −1.3V to one of the Al electrodes (first electrode layer) for 120 seconds, and rinsing it with deionized water after stopping applying the voltage.
Step 7: placing the Al finger electrode cleaned in the previous step into 0.1M sodium polystyrene sulfonate (PSSNa) and 0.015M 3,4-ethylenedioxythiophene (EDOT) aqueous solution, applying a voltage of 1.1V to the other Al electrode (second electrode layer) for 120 seconds, and rinsing it with deionized water after stopping applying the voltage.
Step 8: forming quantum dots using a solution method (20 mg/mL) on the Al finger electrode, with a rotation speed of 2000 rpm and a time of 30 seconds.
Step 9: testing JVL data of the obtained device to determine electrical performance of the obtained device.

Please refer to FIG. 6. In Example 1, the charge transport layers are deposited by electrochemical deposition, which is a difficult process. Compared with Example 1, Example 2 directly heats an entire porous electrode structure to oxidize metal electrodes, so that surfaces of the metal electrodes are covered with corresponding metal oxide charge transport layers. For example, Ti is oxidized to form TiO₂ (first charge transport layer), and Ni is oxidized to form NiOx (second charge transport layer). Comparative Example provides a conventional back contact electrode. Please refer to FIG. 6 for specific test results. In comparison, brightness (cd/cm²), T95 life (hr), and T95@1000 nits (hr) of Examples 1 and 2 are all better than those of Comparative Example, which can be explained that Example 1 and Example 2 have better luminous properties. Furthermore, luminous performance of Example 1 is better than luminous performance of Example 2. A process of Example 1 is more difficult than a process of Example 2, but a product of Example 1 has better effect. Different processes can be selected according to actual needs.

The present invention has the following advantages. The second electrode layer 4 has the plurality of mesh holes 41, which increases specific surface areas of the first electrode layer 2 and the second electrode layer 4, and increase the effective contact area between the second electrode layer 4 and the light-emitting layer 5, thereby increasing the amount of carrier injection and thus improving device efficiency. Furthermore, the framework layer 3 is formed by a solution method, and the second electrode layer 4 is deposited on the upper surface of the framework layer 3 to form a back contact electrode, which do not require photolithography technology, and thus greatly reduces manufacturing cost.

In the above embodiments, the descriptions of each embodiment have their own emphasis, and the part that is not described in detail in a certain embodiment can be referred to the detailed description of the other embodiments above, and will not be repeated here.

The basic concepts have been described above. It is clear that, for those skilled in the art, the above detailed disclosures are only examples and do not constitute a limitation of the present disclosure. Although not expressly stated herein, a person skilled in the art may make various amendments, improvements, and amendments to the present disclosure. Such modifications, improvements, and amendments proposed in the present disclosure still fall within the spirit and scope of the model embodiments of the present disclosure.

At the same time, the present disclosure uses specific words to describe the embodiment of the present disclosure. For example, “one embodiment”, “an embodiment”, and/or “some embodiments” means a feature, structure or feature relating to at least one embodiment of the present disclosure. Therefore, it should be emphasized and noted that the references to “one embodiment” or “an embodiment” or “an alternative embodiment” in different positions in this specification do not necessarily refer to the same embodiment. In addition, certain features or structures in one or more embodiments of the present disclosure may be appropriately combined.

Similarly, it should be noted that, in order to simplify the presentation of the present disclosure and thus aid in the understanding of one or more embodiments of the present disclosure, the description of the embodiments of the present disclosure above sometimes combines multiple features into a single embodiment, drawing, or description thereof. However, this method of disclosure does not mean that the subject matter of the present disclosure requires more features than those mentioned in the claims. In fact, the characteristics of the embodiments are less than all the features of the individual embodiments disclosed above.

Some embodiments use numbers describing the number of components and attributes, and it should be understood that such numbers used for the description of embodiments are modified in some examples by using the modifier “approximately”, “roughly” or “substantially”. Unless otherwise stated, “approximately”, “roughly” or “substantially” indicates that the figures allow for a variation of ±20%. Correspondingly, in some embodiments, the numerical parameters used in the description and claims are approximate values, and the approximate values can be changed according to the required characteristics of the individual embodiments. In some embodiments, the numerical parameters should take into account the specified significant digits and adopt the method of general digit retention. Although the numerical fields and parameters used to confirm the breadth of its range in some embodiments of the present disclosure are approximate values, in the specific embodiments, such numerical values are set as accurately as practicable.

The entire contents of each patent, patent application, patent application disclosure and other materials, such as articles, books, specifications, publications, documents, etc., cited in the present disclosure are hereby incorporated into the present disclosure as a reference, except for application history documents that are inconsistent with or in conflict with the contents of the present disclosure, and other documents that have the widest limitation of the claims of the present disclosure (currently or subsequently attached to the present disclosure). It should be noted that if there is any inconsistency or conflict between the description, definition, and/or use of terms in the ancillary materials of the present disclosure and the content of the present disclosure, the use of the description, definition and/or terminology of the present disclosure shall prevail.

The light-emitting diode and the manufacturing method thereof provided by the embodiments of the present disclosure are described in detail above. The present disclosure uses specific examples to describe principles and embodiments of the present invention. The above description of the embodiments is only for helping to understand solutions of the present disclosure and its core ideas. Furthermore, those skilled in the art may make modifications to the specific embodiments and applications according to ideas of the present invention. In conclusion, the present specification should not be construed as a limitation to the present invention.

1. A light-emitting diode, comprising:
a first electrode layer;
a framework layer disposed on the first electrode layer, wherein a surface of the framework layer close to the first electrode layer has a first opening, a surface of the framework layer away from the first electrode layer has a second opening, the framework layer has a connecting channel connecting the first opening and the second opening, and the framework layer is made of an insulating material;
a second electrode layer covering the surface of the framework layer away from the first electrode layer and exposing at least a part of the second opening; and
a light-emitting layer covering the second electrode layer and the part of the second opening, penetrating into the connecting channel through the second opening, and in electrical contact with the first electrode layer through the first opening.

2. The light-emitting diode according to claim 1, wherein the light-emitting layer comprises a plurality of quantum dots, and a channel size of the connecting channel is greater than a diameter of the quantum dots.

3. The light-emitting diode according to claim 1, wherein the framework layer comprises a plurality of nanoparticles, the nanoparticles are stacked, and gaps between the adjacent nanoparticles are combined to form the connecting channel in the framework layer.

4. The light emitting diode according to claim 3, wherein the nanoparticles cover a surface of the first electrode layer to form the skeleton layer.

5. The light emitting diode according to claim 3, wherein the nanoparticles are disposed on parts of a surface of the first electrode layer.

6. The light-emitting diode according to claim 3, wherein the nanoparticles form multiple layers or a single layer.

7. The light-emitting diode according to claim 3, wherein a diameter of the nanoparticles is 200-1000 nm.

8. The light-emitting diode according to claim 1, wherein the second electrode layer is provided with a plurality of mesh holes at the second opening, and the light-emitting layer penetrates into the connecting channel through the mesh holes and the second opening.

9. The light emitting diode according to claim 1, wherein the second electrode layer has a thickness of 30-50 nm.

10. The light-emitting diode according to claim 1, further comprising a first charge transport layer and a second charge transport layer, wherein the first charge transport layer is disposed on the first electrode layer, the framework layer is disposed on the first charge transport layer, the second electrode layer is disposed on the framework layer, the second charge transport layer is disposed on the second electrode layer, the light-emitting layer is disposed on the second charge transport layer and penetrates into the connecting channel to be electrically connected to the first charge transport layer.

11. The light emitting diode according to claim 10, wherein the second charge transport layer has a thickness of 10-30 nm, or the first charge transport layer has a thickness of 10-50 nm.

12. The light emitting diode according to claim 10, wherein the first charge transport layer is disposed on a surface of the first electrode layer to cover the first electrode layer, or the second charge transport layer is disposed on a surface of the second electrode layer to cover the second electrode layer.

13. The light emitting diode according to claim 10, wherein the light-emitting layer is a quantum dot light-emitting layer and is made of one or more of CdSe, CdS, ZnSe, ZnS, CdTe, ZnTe, CdZnS, CdZnSe, CdZnTe, ZnSeS, ZnSeTe, ZnTeS, CdSeS, CdSeTe, CdTeS, CdZnSeS, CdZnSeTe, CdZnSTe, CdSeSTe, ZnSeSTe, InP, GaP, GaAs, InAs, InAsP, GaAsP, InGaP, InGaAs, PbS, PbSe, PbTe, PbSeS, PbSeTe, CdZnSe/ZnS, CdZnSeS/ZnS, CdTe/ZnS, CdZnSe/ZnS, CdZnSeS/ZnS, CdTe/ZnS, CdTe/CdSe, CdTe/ZnTe, CdSe/CdS, CdSe/ZnS, InP/ZnS, inorganic perovskite semiconductors, and organic-inorganic hybrid perovskite semiconductors; a general formula of the inorganic perovskite semiconductors is AMX₃, where A is Cs⁺, M is one of Pb²⁺, Sn²⁺, Cu²⁺, Ni²⁺, Cd²⁺, Cr²⁺, Mn²⁺, Co²⁺, Fe²⁺, Ge²⁺, Yb²⁺, Eu²⁺, and X is one of Cl⁻, Br⁻ and I⁻; and a general formula of the organic-inorganic hybrid perovskite semiconductors is BMX₃, where B is an organic amine cation, M is one of Pb²⁺, Sn²⁺, Cu²⁺, Ni²⁺, Cd²⁺, Cr²⁺, Mn²⁺, Co²⁺, Fe²⁺, Ge²⁺, Yb²⁺, Eu²⁺, and X is one of Cl⁻, Br⁻ and I⁻; or
the first electrode layer is made of one or more of conductive metal and conductive metal oxide, the conductive metal is one or more of zinc, tin, copper, chromium, platinum, nickel, titanium, aluminum, and silver, and the conductive metal oxide is one or more of ITO and FTO; or
the second electrode layer is made of one or more of conductive metal and conductive metal oxide, the conductive metal is one or more of zinc, tin, copper, chromium, platinum, nickel, titanium, aluminum, and gold, and the conductive metal oxide is one or more of ITO and FTO; or
the first charge transport layer is made of one or more of ZnO, TiO₂, SnO₂, Ta₂O₃, ZrO₂, NiO, TiLiO, ZnAlO, ZnMgO, ZnSnO, ZnLiO, and InSnO; or
the second charge transport layer is made of one or more of NiO_{X}, PEDOT:PSS, CuSCN, and CuO_{X}; or
the insulating material comprises one or more of zirconium dioxide and alumina.

14. A method for manufacturing a light-emitting diode, comprising:
forming a first electrode layer on a substrate;
forming a framework layer on a surface of the first electrode layer, wherein a surface of the framework layer close to the first electrode layer has a first opening, a surface of the framework layer away from the first electrode layer has a second opening, the framework layer has a connecting channel connecting the first opening and the second opening, and the framework layer is made of an insulating material;
evaporating a second electrode layer on a surface of the framework layer, wherein the second electrode layer covers the surface of the framework layer away from the first electrode layer and exposes at least a part of the second opening; and
forming a light-emitting layer on the second electrode layer by a solution method, wherein the light-emitting layer covers the second electrode layer and the part of the second opening, the light-emitting layer penetrates into the connecting channel through the second opening, and the light-emitting layer is in electrical contact with the first electrode layer through the first opening.

15. The method according to claim 14, wherein the forming the framework layer on the surface of the first electrode layer comprises: preparing a solution comprising an insulating material, and depositing the solution comprising the insulating material on the surface of the first electrode layer by a solution method to form the framework layer.

16. The method of claim 15, wherein the insulating material comprises a plurality of nanoparticles, and after depositing the solution comprising the insulating material on the surface of the first electrode layer, the nanoparticles are stacked, and gaps between the adjacent nanoparticles are combined to form the connecting channel in the framework layer.

17. The method according to claim 14, wherein when evaporating the second electrode layer, an evaporation rate is 0.1-2 A/s, an evaporation time is 5000 s-150 s, and the second electrode layer has a thickness of 30-50 nm.

18. The method according to claim 14, after forming the first electrode layer on the substrate, further comprising:
electrochemically depositing a first charge transport layer on a surface of the first electrode layer; or
surface oxidizing the first electrode layer to form the first charge transport layer.

19. The method according to claim 14, after evaporating the second electrode layer on the surface of the framework layer, further comprising:
electrochemically depositing a second charge transport layer on a surface of the second electrode layer; or
surface oxidizing the second electrode layer to form the second charge transport layer.

20. The method according to claim 19, wherein the light-emitting layer is a quantum dot light-emitting layer and is made of one or more of CdSe, CdS, ZnSe, ZnS, CdTe, ZnTe, CdZnS, CdZnSe, CdZnTe, ZnSeS, ZnSeTe, ZnTeS, CdSeS, CdSeTe, CdTeS, CdZnSeS, CdZnSeTe, CdZnSTe, CdSeSTe, ZnSeSTe, InP, GaP, GaAs, InAs, InAsP, GaAsP, InGaP, InGaAs, PbS, PbSe, PbTe, PbSeS, PbSeTe, CdZnSe/ZnS, CdZnSeS/ZnS, CdTe/ZnS, CdZnSe/ZnS, CdZnSeS/ZnS, CdTe/ZnS, CdTe/CdSe, CdTe/ZnTe, CdSe/CdS, CdSe/ZnS, InP/ZnS, inorganic perovskite semiconductors, and organic-inorganic hybrid perovskite semiconductors; a general formula of the inorganic perovskite semiconductors is AMX₃, where A is Cs⁺, M is one of Pb²⁺, Sn²⁺, Cu²⁺, Ni²⁺, Cd²⁺, Cr²⁺, Mn²⁺, Co²⁺, Fe²⁺, Ge²⁺, Yb²⁺, Eu²⁺, and X is one of Cl⁻, Br⁻ and I⁻; and a general formula of the organic-inorganic hybrid perovskite semiconductors is BMX₃, where B is an organic amine cation, M is one of Pb²⁺, Sn²⁺, Cu²⁺, Ni²⁺, Cd²⁺, Cr²⁺, Mn²⁺, Co²⁺, Fe²⁺, Ge²⁺, Yb²⁺, Eu²⁺, and X is one of Cl⁻, Br⁻ and I⁻; or
the first electrode layer is made of one or more of conductive metal and conductive metal oxide, the conductive metal is one or more of zinc, tin, copper, chromium, platinum, nickel, titanium, aluminum, and silver, and the conductive metal oxide is one or more of ITO and FTO; or
the second electrode layer is made of one or more of conductive metal and conductive metal oxide, the conductive metal is one or more of zinc, tin, copper, chromium, platinum, nickel, titanium, aluminum, and gold, and the conductive metal oxide is one or more of ITO and FTO; or
the first charge transport layer is made of one or more of ZnO, TiO₂, SnO₂, Ta₂O₃, ZrO₂, NiO, TiLiO, ZnAlO, ZnMgO, ZnSnO, ZnLiO, and InSnO; or
the second charge transport layer is made of one or more of NiO_{X}, PEDOT:PSS, CuSCN, and CuO_{X}; or
the insulating material comprises one or more of zirconium dioxide and alumina.
